(19) United States
(12) Patent Application Publication
(10) Pub. No.: US 2025/0324791 A1
(43) Pub. Date: Oct. 16, 2025

(54) IMAGE SENSOR AND METHOD OF FABRICATING THE SAME

(71) Applicant: SAMSUNG ELECTRONICS CO., LTD., Suwon-si (KR)

(72) Inventors: Jihyun KWAK, Suwon-si (KR); MINKWAN KIM, Suwon-si (KR); HYUNCHUL KIM, Suwon-si (KR); CHANG KYU LEE, Suwon-si (KR)

(73) Assignee: SAMSUNG ELECTRONICS CO., LTD., Suwon-si (KR)

(21) Appl. No.: 19/018,887

(22) Filed: Jan. 13, 2025

(30) Foreign Application Priority Data
Apr. 12, 2024 (KR) 10-2024-0049476

(51) Int. Cl. H10F 39/00; H10F 39/18

(52) U.S. Cl. CPC H10F 39/8053; H10F 39/182; H10F 39/811

(57) ABSTRACT

An image sensor may include a semiconductor substrate including a plurality of unit pixels, an anti-reflection layer on the semiconductor substrate, color filters on the anti-reflection layer, grid structures disposed between adjacent color filters among the color filters, and a grid gap defined in each of the grid structures. The grid structures may include a first grid structure including an insulating fence and a second grid structure including an insulating fence, the second grid structure having a width larger than the first grid structure. The first grid structure may be spaced apart from the second grid structure, and the grid gap may be defined as a space that is extended from the insulating fence to the anti-reflection layer.

### CROSS-REFERENCE TO RELATED APPLICATION

This application claims priority under 35 U.S.C. § 119 to Korean Patent Application No. 10-2024-0049476, filed on Apr. 12, 2024, in the Korean Intellectual Property Office, the disclosure of which is hereby incorporated by reference in its entirety.

### BACKGROUND

One or more example embodiments of the disclosure relate to an image sensor and a method of fabricating the same, and in particular, to a complementary metal oxide semiconductor (CMOS) image sensor and a method of fabricating the same.

An image sensor is a semiconductor device configured to convert an optical image to electric signals. With the recent development of computer and communication industries, there is an increasing demand for high-performance image sensors in a variety of applications such as digital cameras, camcorders, personal communication systems, gaming machines, security cameras, micro-cameras for medical applications, and/or robots.

As semiconductor devices become more highly integrated, image sensors also become highly integrated. Thus, each pixel becomes smaller in size. Accordingly, there is an increasing demand for an image sensor that is configured to exhibit a small cross-talk and high sensitivity even when an area of each pixel is small.

### SUMMARY

An embodiment of the inventive concept provides an image sensor having a small pixel size and a method of fabricating the same.

An embodiment of the inventive concept provides an image sensor having high sensitivity and a method of fabricating the same.

An embodiment of the inventive concept provides an image sensor with a reduced cross-talk issue and a method of fabricating the same.

According to an embodiment of the inventive concept, an image sensor may include a semiconductor substrate including a plurality of unit pixels, an anti-reflection layer on the semiconductor substrate, color filters on the anti-reflection layer, grid structures disposed between adjacent color filters among the color filters, and a grid gap defined in each of the grid structures. The grid structures may include a first grid structure including an insulating fence and a second grid structure including an insulating fence, the second grid structure having a width larger than the first grid structure. The first grid structure may be spaced apart from the second grid structure, and the grid gap may be defined as a space that is extended from the insulating fence to the anti-reflection layer.

According to an embodiment of the inventive concept, an image sensor may include a semiconductor substrate having a first surface and a second surface, the second surface being opposite to the first surface, a fixed charge layer on the semiconductor substrate, an anti-reflection layer on the fixed charge layer, color filters on the anti-reflection layer, grid structures disposed between adjacent color filters among the color filters, and a grid gap defined in each of the grid structures. The grid structures may include a first grid structure including a fence layer including a conductive material and an insulating fence on the fence layer and a second grid structure including a shield fence layer whose largest width is larger than a width of the fence layer. The first grid structure may be spaced apart from the second grid structure, a topmost portion of the grid gap in the first grid structure may be defined in the insulating fence, and a top surface of the fixed charge layer may be exposed by the grid gap.

According to an embodiment of the inventive concept, an image sensor may include a substrate having a first surface and a second surface, the second surface being opposite to the first surface, a transfer gate disposed on the first surface, a fixed charge layer disposed on the second surface, an anti-reflection layer on the fixed charge layer, color filters on the anti-reflection layer, grid structures disposed between adjacent color filters among the color filters, and a grid gap defined in each of the grid structures. The grid structures may include a first grid structure including a fence layer and an insulating fence on the fence layer, and a second grid structure spaced apart from the first grid structure, the fence layer including a conductive material. The second grid structure may include a shield fence layer wider than the fence layer and an insulating fence on the shield fence layer. The grid gap may be defined by the insulating fence and the anti-reflection layer. The insulating fence included in the first grid structure may include a protruding fence portion of which an outer side surface is in contact with a side surface of the first grid structure, a body fence portion on the protruding fence portion, and an intervening fence portion between the color filter and the protruding fence portion. The grid gap in the first grid structure may be defined by the protruding fence portion and a side surface of the body fence portion.

### BRIEF DESCRIPTION OF THE DRAWINGS

The above and other objects and features of the disclosure will become apparent by describing in detail example embodiments thereof with reference to the accompanying drawings.

FIG. 1 is a block diagram schematically illustrating an image sensor according to an example embodiment of the inventive concept.

FIG. 2 is a circuit diagram illustrating an active pixel sensor array of an image sensor according to an example embodiment of the inventive concept.

FIG. 3 is a plan view illustrating an image sensor according to an example embodiment of the inventive concept.

FIG. 4A is a sectional view taken along a line A-A′ of FIG. 3.

FIG. 4B is an enlarged sectional view illustrating a portion ‘X’ of FIG. 4A.

FIG. 4C is an enlarged sectional view illustrating the portion ‘X’ of the image sensor of FIG. 4A.

FIG. 5A is a sectional view, which is taken along the line A-A′ of FIG. 3 to illustrate an image sensor according to an example embodiment of the inventive concept.

FIG. 5B is an enlarged sectional view illustrating a portion ‘X’ of FIG. 5A.

FIG. 6A is a sectional view, which is taken along the line A-A′ of FIG. 3 to illustrate an image sensor according to an example embodiment of the inventive concept.

FIG. 6B is an enlarged sectional view illustrating a portion ‘X’ of FIG. 6A.

FIG. 7A is a sectional view, which is taken along the line A-A′ of FIG. 3 to illustrate an image sensor according to an example embodiment of the inventive concept.

FIG. 7B is an enlarged sectional view illustrating a portion ‘X’ of FIG. 7A.

FIGS. 8A, 9A, 10A, 11A, 12A, and 13A are sectional views, which are taken along the line A-A′ of FIG. 3 to illustrate a method of fabricating an image sensor, according to an example embodiment of the inventive concept.

FIGS. 8B, 9B, 10B, 11B, 12B, and 13B are enlarged sectional views illustrating the portion ‘X’ of FIG. 4 and illustrating a method of fabricating an image sensor, according to an example embodiment of the inventive concept.

### DETAILED DESCRIPTION

Example embodiments of the inventive concepts will now be described more fully with reference to the accompanying drawings, in which example embodiments are shown.

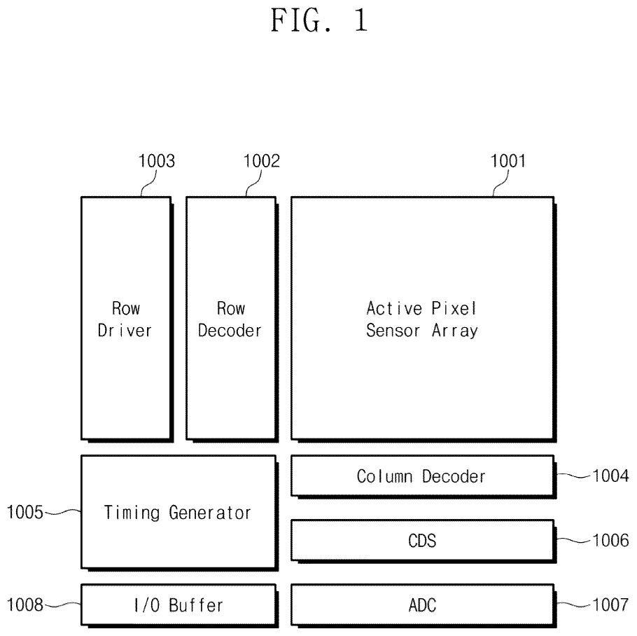

FIG. 1 is a block diagram schematically illustrating an image sensor according to an example embodiment of the inventive concept.

Referring to FIG. 1, an image sensor may include an active pixel sensor array 1001, a row decoder 1002, a row driver 1003, a column decoder 1004, a timing generator 1005, a correlated double sampler (CDS) 1006, an analog-to-digital converter (ADC) 1007, and an input/output (I/O) buffer 1008.

The active pixel sensor array 1001 may include a plurality of unit pixels, which are two-dimensionally arranged, and may be configured to convert an optical signal to an electrical signal. The active pixel sensor array 1001 may be driven by a plurality of driving signals, such as a pixel selection signal, a reset signal, and a charge transfer signal, which are transmitted from the row driver 1003. In addition, the converted electrical signal may be provided to the CDS 1006.

The row driver 1003 may be configured to provide a plurality of driving signals for driving the plurality of unit pixels to the active pixel sensor array 1001, based on a result decoded by the row decoder 1002. In the case where the unit pixels are arranged in a matrix shape (i.e., in rows and columns), the driving signals may be provided to respective rows.

The timing generator 1005 may be configured to provide a timing signal and a control signal to the row decoder 1002 and the column decoder 1004.

The CDS 1006 may be configured to receive the electric signals generated by the active pixel sensor array 1001 and to perform a holding and sampling operation on the received electric signals. The CDS 1006 may perform a double sampling operation using a specific noise level and a signal level of the electric signal and then may output a difference level corresponding to a difference between the noise and signal levels.

The ADC 1007 may be configured to convert an analog signal, which contains information on the difference level outputted from the CDS 1006, to a digital signal and to output the converted digital signal.

The I/O buffer 1008 may be configured to latch digital signals output from the ADC 1007 and then to sequentially output the latched digital signals to an image signal processing unit (not shown), based on the result decoded by the column decoder 1004.

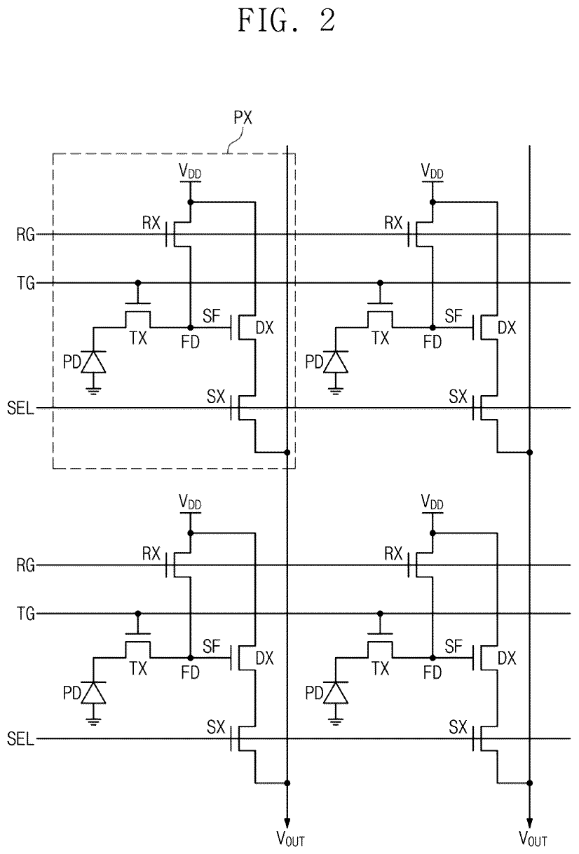

FIG. 2 is a circuit diagram illustrating an active pixel sensor array of an image sensor according to an example embodiment of the inventive concept.

Referring to FIGS. 1 and 2, the active pixel sensor array 1001 may include a plurality of pixel regions PX, which are arranged in a matrix shape. Each pixel region PX may include a transfer transistor TX. Each pixel region PX may further include logic transistors RX, SX, and DX. The logic transistors may include a reset transistor RX, a selection transistor SX, and/or a source follower transistor DX. The transfer transistor TX may include a transfer gate TG. Each of the pixel regions PX may further include a photoelectric conversion part PD and a floating diffusion region FD. The logic transistors RX, SX, and DX may be shared by the pixel regions PX.

The photoelectric conversion part PD may be configured to generate photocharges whose amount is in proportional to an amount of light incident from an outside and to store the photocharges therein. The photoelectric conversion part PD may include a photodiode, a photo transistor, a photogate, a pinned photodiode, or any combination thereof. The transfer transistor TX may be configured to transfer electric charges, which are generated in the photoelectric conversion part PD, to the floating diffusion region FD. The floating diffusion region FD may be configured to receive and cumulatively store therein the electric charges, which are generated in the photoelectric conversion part PD. The source follower transistor DX may be controlled, based on an amount of photocharges stored in the floating diffusion region FD.

The reset transistor RX may be configured to periodically discharge or reset the photocharges accumulated in the floating diffusion region FD. The reset transistor RX may include drain and source electrodes, which are connected to the floating diffusion region FD and a power voltage VDD, respectively. If the reset transistor RX is turned on, the power voltage VDD connected to the source electrode of the reset transistor RX may be applied to the floating diffusion region FD. Thus, if the reset transistor RX is turned on, the electric charges accumulated in the floating diffusion region FD may be discharged; that is, the floating diffusion region FD may be reset.

The source follower transistor DX including a source follower gate electrode SF may be used as a source follower buffer amplifier. The source follower transistor DX may be configured to amplify a variation in electric potential of the floating diffusion region FD and to output the amplified signal to an output line Vout.

The selection transistor SX including a selection gate electrode SEL may be used to select one of the rows of the pixel regions PX, during reading operations. When the selection transistor SX is turned on, the power voltage VDD may be applied to a drain electrode of the source follower transistor DX.

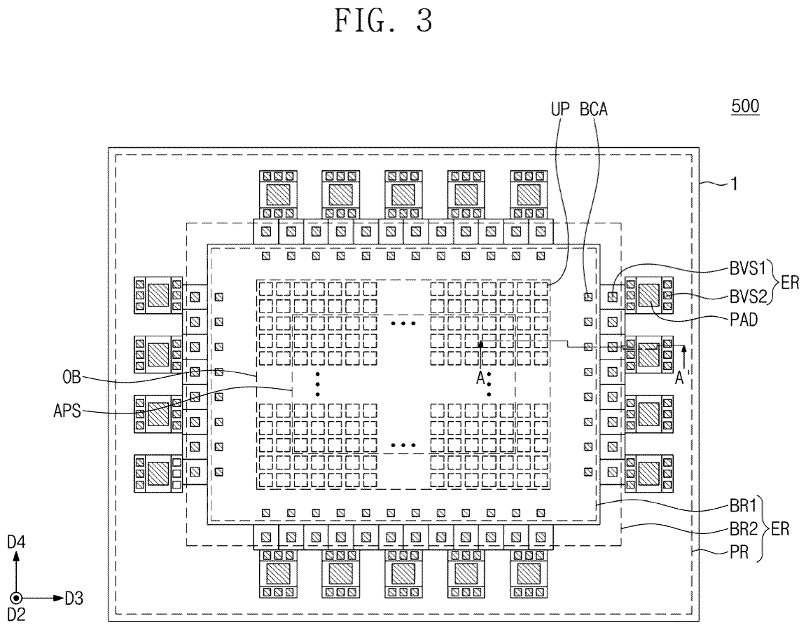

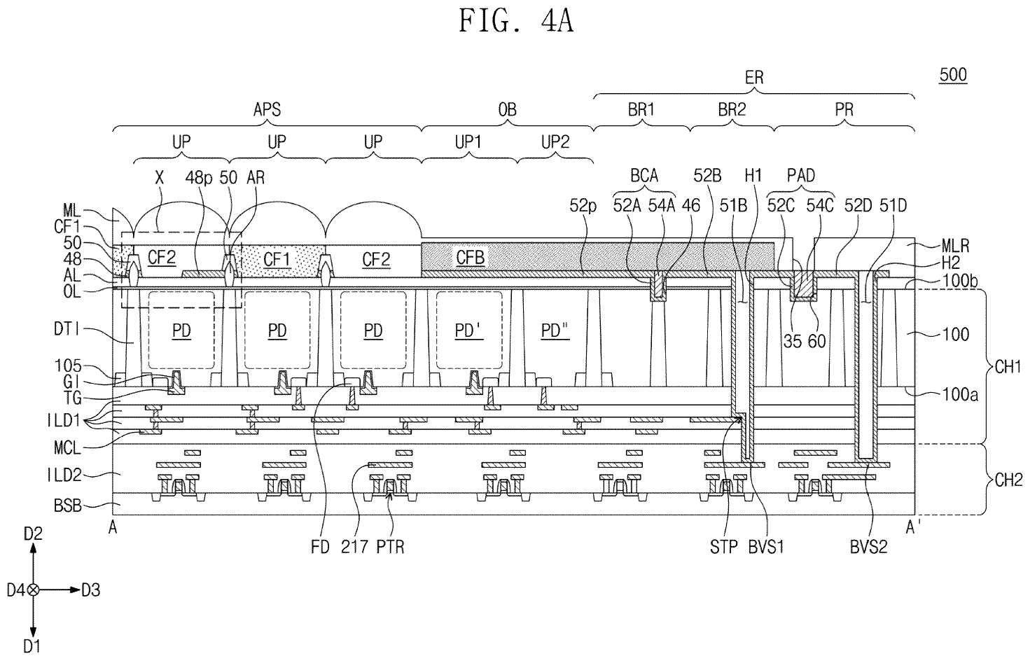

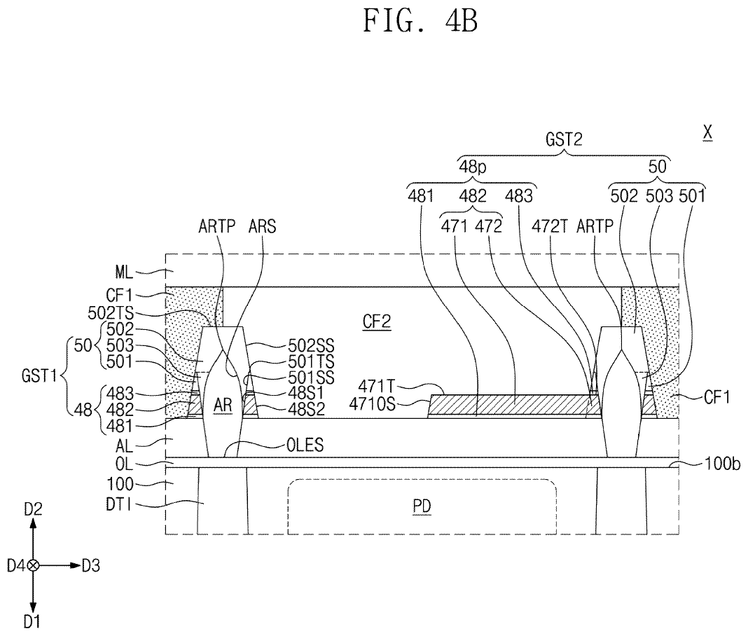

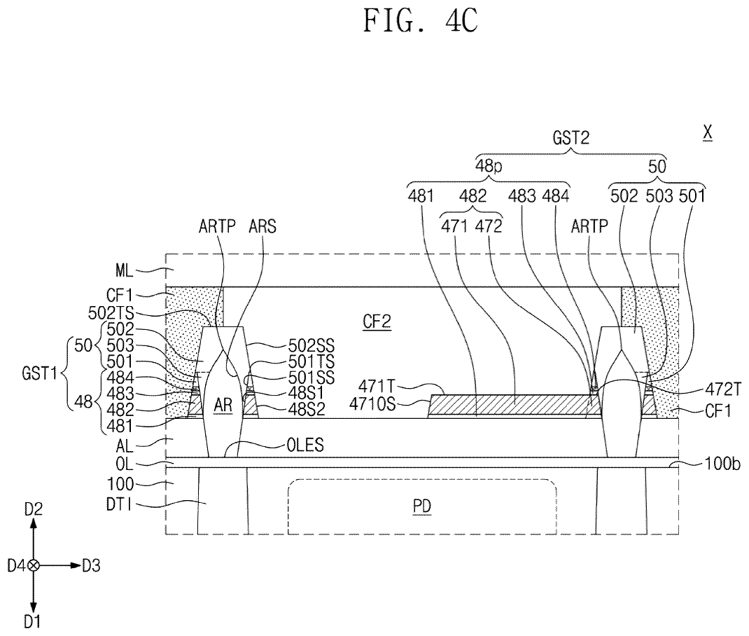

FIG. 3 is a plan view illustrating an image sensor according to an example embodiment of the inventive concept. FIG. 4A is a sectional view taken along a line A-A′ of FIG. 3. FIG. 4B is an enlarged sectional view illustrating a portion ‘X’ of FIG. 4A.

Referring to FIGS. 3, 4A, and 4B, an image sensor 500 according to an example embodiment of the inventive concept may have a structure, in which a first sub-chip CHI and a second sub-chip CH2 are bonded to each other. The first sub-chip CH1 may be disposed on the second sub-chip CH2. The first sub-chip CHI may include a substrate 100. In an example embodiment, the substrate 100 may be a single crystalline silicon wafer, a silicon epitaxial layer, or a silicon-on-insulator (SOI) wafer. In an embodiment, the substrate 100 may be doped with impurities of a first conductivity type. For example, the first conductivity type may be a p-type.

The substrate 100 may include a first surface 100a and a second surface 100b, which are opposite to each other. For example, the first and second surfaces 100a and 100b may be normal to a first direction D1 and a second and direction D2. The first direction D1 and the second direction D2 may be antiparallel to each other. The substrate 100 may include a pixel array region APS, an optical black region OB, and an edge region ER. The substrate 100 may include a plurality of pixel regions. In an embodiment, the substrate 100 may include a plurality of unit pixels UP.

Each of the pixel array region APS and the optical black region OB may include a plurality of the unit pixels UP. The unit pixels UP may be arranged in a third direction D3 and a fourth direction D4. The optical black region OB may enclose the pixel array region APS. The edge region ER may enclose the pixel array region APS and the optical black region OB. The edge region ER may include a contact region BR1, a via region BR2, and a pad region PR. The via region BR2 may be placed between the contact region BR1 and the pad region PR. The pad region PR may be the outermost region of the edge region ER.

In the pixel array region APS and the optical black region OB, a substrate isolation portion DTI may be disposed in the substrate 100 to separate or delimit the unit pixels UP in the pixel array region APS and separate or delimit regions in the substrate 100 in the optical black region OB. The substrate isolation portion DTI may be extended to the contact region BR1 of the edge region ER. The substrate isolation portion DTI may have a mesh shape or a net shape, when viewed in a plan view.

Back-side contacts BCA, back-side via patterns BVS1 and BVS2, and back-side conductive pads PAD may be disposed in the edge region ER and on the second surface 100b of the substrate 100. The back-side via patterns BVS1 and BVS2 may include a first back-side via pattern BVS1 and a second back-side via pattern BVS2. Column signals and/or row signals may be transmitted between the first and second sub-chips CH1 and CH2 through the back-side via patterns BVS1 and BVS2.

The substrate isolation portion DTI may be provided in the substrate 100. The substrate isolation portion DTI may separate the unit pixels UP from each other. Between the unit pixels UP, the substrate isolation portion DTI may penetrate the substrate 100 in the second direction D2.

The substrate isolation portion DTI may penetrate only a portion of the substrate 100. In this case, the substrate 100 may include an impurity region that is aligned to the substrate isolation portion DTI and is doped with impurities of a different conductivity type from the photoelectric conversion region PD, and thus, pixels may be defined.

The substrate isolation portion DTI may be extended from the first surface 100a toward the second surface 100b. When viewed in a plan view, the substrate isolation portion DTI may have a mesh shape or a net shape that is formed by lines extended in the third and fourth directions D3 and D4. The substrate isolation portions DTI may have a decreasing width as a distance from the first surface 100a of the substrate 100 increases in a direction toward the second surface 100b.

In an embodiment, the substrate isolation portion DTI may be extended from the second surface 100b toward the first surface 100a. The width of the substrate isolation portions DTI may decrease as a distance from the second surface 100b of the substrate 100 increases in a direction toward the first surface 100a.

In an embodiment, the substrate isolation portion DTI may have a uniform width. In an embodiment, the substrate isolation portion DTI may have a shape whose width is largest at an intermediate level thereof in the first direction D1.

Each of the substrate isolation portions DTI may include a gapfill insulating pattern (not shown), a separation insulating pattern (not shown), and a separation conductive pattern (not shown).

The separation conductive pattern (not shown) may be spaced apart from the substrate 100. The separation conductive pattern (not shown) may include a doped polysilicon layer or a doped silicon germanium layer. For example, the polysilicon and the silicon germanium layer may be doped with impurities (e.g., boron, phosphorus, or arsenic). In an embodiment, the separation conductive pattern (not shown) may include a metal layer.

The gapfill insulating pattern (not shown) may be interposed between the separation conductive pattern (not shown) and a first interlayer insulating layer ILD1. The separation conductive pattern (not shown) may be spaced apart from the first surface 100a of the substrate 100 by the gapfill insulating pattern (not shown). The separation insulating pattern (not shown) may be interposed between the separation conductive pattern (not shown) and the substrate 100 and between the gapfill insulating pattern (not shown) and the substrate 100.

The gapfill insulating pattern (not shown) and the separation insulating pattern (not shown) may be formed of or include an insulating material having a refractive index different from the substrate 100. In an embodiment, the gapfill insulating pattern (not shown) and the separation insulating pattern (not shown) may be formed of or include silicon oxide.

A shallow device isolation pattern 105 may be included in the substrate 100. The shallow device isolation pattern 105 may be extended from the second surface 100b into the substrate 100 and may be provided in a corresponding one of the unit pixels UP. In the pixel array region APS, the shallow device isolation pattern 105 may be provided to delimit active regions ACT adjacent to the second surface 100b of the substrate 100. The active regions ACT may be provided for the transistors TX, RX, DX, and SX of FIG. 2.

In the unit pixels UP, photoelectric conversion parts PD may be respectively disposed in the substrate 100. The photoelectric conversion parts PD may be doped with impurities, which are of a second conductivity type that is different from the first conductivity type of the substrate 100. For example, the second conductivity type may be an n-type. The photoelectric conversion part PD of the n type and the substrate 100 of the p type may form a pn junction serving as a photo diode.

Referring to FIG. 4A, in the unit pixels UP, the transfer gate TG may be disposed on the first surface 100a of the substrate 100. A portion of the transfer gate TG may be extended into the substrate 100. The transfer gate TG may be of a vertical type. Alternatively, the transfer gate TG may be of a planar type; for example, the transfer gate TG may not be extended into the substrate 100 and may have a flat shape. A gate insulating layer GI may be interposed between the transfer gate TG and the substrate 100. The floating diffusion region FD may be disposed in a portion of the substrate 100 that is placed at a side of the transfer gate TG. The floating diffusion region FD may be doped with impurities of, for example, the second conductivity type.

A first unit pixel UP1 and a second unit pixel UP2 may be disposed on the optical black region OB of the substrate 100. In the first unit pixel UP1, a black photoelectric conversion part PD′ may be provided in the substrate 100. In the second unit pixel UP2, a dummy region PD″ may be provided in the substrate 100. The black photoelectric conversion part PD′ may be doped with impurities, which are of a second conductivity type different from the first conductivity type. The second conductivity type may be, for example, an n-type. The black photoelectric conversion part PD′ may have a structure similar to the photoelectric conversion part PD but may not be used for the operation of converting light to electric signals, unlike the photoelectric conversion part PD. A signal, which is generated in the black photoelectric conversion part PD′, may be used to generate a reference signal of a dark level. The dummy region PD″ may not be doped with an impurity. A signal, which is generated in the dummy region PD″, may be used as information for removing a process noise.

The first interlayer insulating layer ILD1 and first interlayer interconnection lines MCL may be provided on the first surface 100a of the substrate 100.

The first interlayer insulating layer ILD1 may be provided on the first surface 100a of the substrate 100 to cover the first surface 100a. The first interlayer insulating layer ILD1 may be a composite layer including at least one of silicon oxide, silicon nitride, silicon oxynitride, or porous low-k dielectric materials. The first interlayer interconnection lines MCL may be provided in the first interlayer insulating layer ILD1. The floating diffusion region FD may be connected to the first interlayer interconnection lines MCL.

A second interlayer insulating layer ILD2 may be provided below the first interlayer insulating layer ILD1. Second interlayer interconnection lines 217 may be provided in the second interlayer insulating layer ILD2. Peripheral transistors PTR may be disposed in the second interlayer insulating layer ILD2.

A sub-substrate BSB may be provided below the second interlayer insulating layer ILD2. Circuits, which constitute components represented in blocks in FIG. 1 other than the active pixel array, may be disposed on the sub-substrate BSB.

A fixed charge layer OL may be provided on the second surface 100b of the substrate 100. The fixed charge layer OL may prevent electric charges (i.e., electrons or holes), which are generated by defects that are present on the second surface 100b of the substrate 100, from being moved into the photoelectric conversion regions PD. The fixed charge layer OL may have a single-or multi-layered structure.

The fixed charge layer OL may include metal oxide or metal fluoride containing at least one metallic element from among hafnium (Hf), zirconium (Zr), aluminum (Al), tantalum (Ta), titanium (Ti), yttrium (Y) and lanthanum (La). For example, the fixed charge layer OL may include an aluminum oxide layer. The fixed charge layer OL may be used as an etch stop layer.

An anti-reflection layer (or structure) AL may be provided. The anti-reflection layer AL may be provided on the substrate 100. The anti-reflection layer AL may be disposed on the fixed charge layer OL. The anti-reflection layer AL may have a single-or multi-layered structure. The anti-reflection layer AL may be formed of or include an insulating material having a high transmittance.

Grid structures GST1 and GST2 may be disposed on the anti-reflection layer AL. The grid structures GST1 and GST2 may be overlapped with the substrate isolation portion DTI, when viewed in a plan view. The grid structures GST1 and GST2 may include a first grid structure GST1 and a second grid structure GST2, which are spaced apart from each other. The first and second grid structures GST1 and GST2 may be adjacent to each other and may be spaced apart from each other. The grid structures GST1 and GST2 may prevent a cross-talk issue from occurring between adjacent ones of the pixel regions. A width of the second grid structure GST2 may be larger than a width of the first grid structure GST1.

A grid gap (e.g., air gap) AR may be defined in each of the first and second grid structures GST1 and GST2.

In the pixel array region APS, color filters CF1 and CF2 may be disposed between the grid structures GST1 and GST2. For example, one color filter CF1 or CF2 may be disposed between the first grid structure GST1 and the second grid structure GST2.

Each of the color filters CF1 and CF2 may have one of blue, green, and red colors. In an embodiment, the color filters CF1 and CF2 may be provided to have other colors, such as cyan, magenta, or yellow. In an image sensor according to an embodiment, the color filters CF1 and CF2 may be arranged in a form of Bayer pattern. Alternatively, the color filters CF1 and CF2 may be arranged in a form of a 2×2 tetra pattern, a 3×3 nona pattern, or a 4×4 hexadeca pattern.

A protection layer (not shown) may be provided on the grid structures GST1 and GST2. The protection layer (not shown) may conformally cover the grid structures GST1 and GST2.

In the pixel array region APS, micro lenses ML may be disposed on the color filters CF1 and CF2. The micro lenses ML may have edge portions that are in contact with each other and are connected to each other.

An optical black liner 52p may be disposed on the optical black region OB. The optical black liner 52p may include a conductive material. The optical black liner 52p may include at least one of a titanium layer, a titanium nitride layer, or a tungsten layer and may have a single-or multi-layered structure.

An optical black pattern CFB may be provided on the edge region ER. In an embodiment, the optical black pattern CFB may be formed of or include the same material as a blue color filter.

In the edge region ER, a lens residual layer MLR may be disposed on the optical black pattern CFB. The lens residual layer MLR may be formed of or include the same material as the micro lenses ML. In the pad region PR, an opening 35 may be formed in the lens residual layer MLR to expose the back-side conductive pad PAD.

In the contact region BR1, the back-side contact BCA may be disposed in a back-side contact trench 46 that is formed to penetrate the anti-reflection layer (or structure) AL and a portion of the substrate 100. The back-side contact BCA may be in contact with the substrate isolation portion DTI. The back-side contact BCA may include a contact conductive pattern 52A on a side surface of the back-side contact trench 46 and a contact metal pattern 54A on the contact conductive pattern 52A.

The contact conductive pattern 52A may conformally cover an inner surface of the back-side contact trench 46. The contact conductive pattern 52A may be connected to the optical black liner 52p.

The contact metal pattern 54A may fill the back-side contact trench 46. The contact metal pattern 54A may be formed of or include, for example, aluminum.

The back-side contacts BCA may be in contact with the substrate isolation portion DTI. A negative bias may be applied to the separation conductive pattern (not shown) of the substrate isolation portion DTI through the back-side contacts BCA. The separation conductive pattern (not shown) may be used as a common bias line. Thus, it may be possible to anchor holes, which are present on a surface of the substrate 100 that is in contact with the substrate isolation portion DTI, and thereby to improve a dark current property.

Although not shown, the optical black liner 52p may be disconnected from the contact conductive pattern 52A. An insulating material may be interposed between the optical black liner 52p and the contact conductive pattern 52A. For example, an insulating material, such as SiO₂ and Al₂O₃ may be interposed between the optical black liner 52p and the contact conductive pattern 52A.

In the via region BR2, the first back-side vias BVS1 may be disposed on the second surface 100b of the substrate 100. In the pad region PR, the back-side conductive pads PAD and the second back-side vias BVS2 may be disposed on the second surface 100b of the substrate 100. The second back-side vias BVS2 may be grouped together in predetermined numbers, and the groups of the second back-side vias BVS2 may be disposed around the back-side conductive pads PAD, respectively. An external signal may be input or output through the back-side conductive pads PAD. The back-side conductive pads PAD may be used as an interface of the external signal.

The back-side conductive pad PAD may be placed in a back-side pad trench 60. The back-side conductive pad PAD may include a pad conductive pattern 52c and a pad metal pattern 54c. The pad conductive pattern 52c may conformally cover side and bottom surfaces of the back-side pad trench 60.

The pad conductive pattern 52c may be formed of or include the same material as the contact conductive pattern 52A and may have the same thickness as the contact conductive pattern 52A. The pad conductive pattern 52c may include at least one of a titanium layer, a titanium nitride layer, or a tungsten layer and may have a single-or multi-layered structure. The pad metal pattern 54c may be formed of or include, for example, aluminum. The pad metal pattern 54c may fill the back-side pad trench 60.

The back-side contact BCA and the first back-side via pattern BVS1 may be connected to each other by a connection conductive pattern 52B.

The first back-side via pattern BVS1 may be provided on the second surface 100b of the substrate 100. The first back-side via pattern BVS1 may be disposed in a first back-side via hole H1 penetrating the anti-reflection structure AL and a portion of the substrate 100. The first back-side via pattern BVS1 may conformally cover a side surface of the first back-side via hole H1.

The first back-side via pattern BVS1 and the contact conductive pattern 52A may be electrically connected to each other by the connection conductive pattern 52B. The connection conductive pattern 52B may be disposed on the anti-reflection layer AL and between the first back-side via pattern BVS1 and the contact conductive pattern 52A. The first back-side via pattern BVS1, the connection conductive pattern 52B, and the contact conductive pattern 52A may be provided to have a continuous structure. The first interlayer interconnection lines MCL and the second interlayer interconnection lines 217 may be electrically connected to each other by the first back-side via pattern BVS1.

The first back-side via pattern BVS1 may include a stepwise portion STP. In the stepwise portion STP, the first back-side via pattern BVS1 may be connected to the first interlayer interconnection lines MCL. A lowermost surface of the first back-side via pattern BVS1 may be connected to the second interlayer interconnection line 217.

A first low-refraction protection pattern 51B may be disposed on the first back-side via pattern BVS1. The first low-refraction protection pattern 51B may have a refractive index that is smaller than the color filters CF1 and CF2. For example, the first low-refraction protection pattern 51B may have a refractive index of about 1.3 or lower.

Although not shown, a low-refraction capping pattern (not shown) may be disposed on the first low-refraction protection pattern 51B. In this case, a top surface of the first low-refraction protection pattern 51B may be concave.

The second back-side via pattern BVS2 may be disposed in a second back-side via hole H2 penetrating the anti-reflection structure AL and a portion of the substrate 100. The second back-side via pattern BVS2 may be provided to penetrate the anti-reflection structure AL, the substrate 100, the first interlayer insulating layer ILD1, and a portion of the second interlayer insulating layer ILD2. The second back-side via pattern BVS2 may be connected to at least one of the second interlayer interconnection lines 217. Although not shown, the second back-side via pattern BVS2 may be connected to at least one of the first interlayer interconnection lines MCL. The second back-side vias BVS2 may fill the second back-side via hole H2 and may conformally cover an inner side surface and a bottom surface of the second back-side via hole H2. The second back-side via pattern BVS2 may include the same material as the first contact conductive pattern 52A. The second back-side via pattern BVS2 may include at least one of a titanium layer, a titanium nitride layer, or a tungsten layer and may have a single-or multi-layered structure. One of the second back-side via patterns BVS2 may be electrically connected to one of the back-side conductive pads PAD by one of via connection lines 52D.

A second low-refraction protection pattern 51D may be disposed on the second back-side via pattern BVS2.

Referring back to FIG. 4B, the first grid structure GST1, the second grid structure GST2, and the grid gap AR will be described in more detail below.

The first grid structure GST1 may include a fence layer 48 on the anti-reflection layer AL and an insulating fence 50 on the fence layer 48. The second grid structure GST2 may include a shield fence layer 48p and the insulating fence 50 on the shield fence layer 48p. The insulating fences 50 of the first and second grid structures GST1 and GST2 may have the same structure.

The fence layer 48 of the first grid structure GST1 may include a lower fence layer 481 on the anti-reflection layer AL, a conductive fence layer 482 on the lower fence layer 481, and an upper fence layer 483 on the conductive fence layer 482.

The lower fence layer 481 of the first grid structure GST1 may include an insulating material. The lower fence layer 481 of the first grid structure GST1 may be in contact with a top surface of the anti-reflection layer AL.

The conductive fence layer 482 of the first grid structure GST1 may include a conductive material. The conductive fence layer 482 of the first grid structure GST1 may be formed of or include at least one of metallic materials.

The upper fence layer 483 of the first grid structure GST1 may include an insulating material. The upper fence layer 483 of the first grid structure GST1 may be in contact with the insulating fence 50.

The shield fence layer 48p of the second grid structure GST2 may have a width that is larger than the fence layer 48 of the first grid structure GST1. The shield fence layer 48p may include the lower fence layer 481 on the anti-reflection layer AL, the conductive fence layer 482 on the lower fence layer 481, and the upper fence layer 483 on the conductive fence layer 482. The shield fence layer 48p may be disposed between the insulating fence 50 and the anti-reflection layer AL.

A width of the lower fence layer 481 of the shield fence layer 48p of the second grid structure GST2 may be larger than a width of the lower fence layer 481 of the first grid structure GST1. The conductive fence layer 482 of the shield fence layer 48p may include a first conductive fence layer 471 and a second conductive fence layer 472. The first conductive fence layer 471 may be extended in a direction parallel to an extension direction of the substrate 100 and may be defined as the conductive fence layer 482 spaced apart from the upper fence layer 483. The second conductive fence layer 472 may be defined as the conductive fence layer 482 between the first conductive fence layer 471 and the grid gap AR. A level of a topmost surface 471T of the first conductive fence layer 471 may be lower than a level of a topmost surface 472T of the second conductive fence layer 472. An outer side surface 471OS of the first conductive fence layer 471 (or the shield fence layer 48p) may be inclined at an angle. A top surface of the shield fence layer 48p may be in contact with the color filter CF1 or CF2. For example, a top surface of the upper fence layer 483 of the shield fence layer 48p may be in contact with a corresponding one of the color filters CF1 and CF2.

The upper fence layer 483 of the second grid structure GST2 may be similar to the upper fence layer 483 of the fence layer 481 of the first grid structure GST1.

The insulating fence 50 of the first and second grid structure GST1 or GST2 may include a protruding fence portion 503 in contact with a side surface of the fence layer 48 of the first grid structure GST1 or the shield fence layer 48p of the second grid structure GST2, a body fence portion 502 on the protruding fence portion 503, and an intervening fence portion 501 between the color filter CF1 or CF2 and the protruding fence portion 503. The intervening fence portion 501 may be in contact with the upper fence layer 483.

The grid gap AR may be defined in each of the first and second grid structures GST1 and GST2. The grid gap AR may be defined as a space that is extended from the insulating fence 50 to the anti-reflection layer AL. The grid gap AR may be defined by an inner side surface of the insulating fence 50, an exposed inner side surface of the anti-reflection layer AL, and an exposed top surface of the fixed charge layer OL.

The grid gap AR may be defined by inner side surfaces of the grid structure GST1 or GST2. The inner side surface of the grid structure GST1 or GST2 may be defined as a gap side surface ARS, and the grid gap AR may be defined by the gap side surface ARS. The gap side surface ARS may be defined by the inner side surface of the insulating fence 50 and the inner side surface of the anti-reflection layer AL. The gap side surface ARS may include a curved portion.

The fence layer 48 may have an inner side surface 48S1, which is in contact with the protruding fence portion 503, and an outer side surface 48S2, which is in contact with the color filter CF1 or CF2. An outer side surface of the protruding fence portion 503 may be in contact with an outer side surface 501SS of the intervening fence portion 501. The outer side surface of the protruding fence portion 503 may be in contact with the inner side surface 48S1 of the fence layer 48. An inner side surface of the protruding fence portion 503 may define a grid gap. A topmost surface 501TS of the intervening fence portion 501 may be in contact with the body fence portion 502. The protruding fence portion 503 may have a shape protruding from the body fence portion 502 toward the substrate 100. An outer side surface 502SS of the body fence portion 502 may be inclined at an angle with respect to the first surface 100a of the substrate 100. The outer side surface 502SS of the body fence portion 502 may be in contact with the color filter CF1 or CF2. A topmost surface 502TS of the body fence portion 502 may be in contact with two different color filters CF1 or CF2. The topmost surface 502TS of the body fence portion 502 may be spaced apart from the micro lens ML.

The outer side surface 502SS of the body fence portion 502 may be spaced apart from the outer side surface of the protruding fence portion 503. The largest width of the shield fence layer 48p may be larger than the largest width of the insulating fence 50.

A gap topmost point ARTP may be defined at an uppermost level of the grid gap AR. The uppermost portion of the grid gap AR may be defined in the insulating fence 50. The gap topmost point ARTP may be placed between the topmost surface 502TS of the body fence portion 502 and the topmost surface 501TS of the intervening fence portion 501. A top surface OLES of the fixed charge layer OL may be exposed by the grid gap AR.

According to an embodiment of the inventive concept, each of the grid structures GST1 and GST2 may be provided to have the grid gap AR defined therein. In an embodiment, the grid structures GST1 and GST2 may include the first grid structure GST1 and the second grid structure GST2, which is spaced apart from the first grid structure GST1 and is wider than the first grid structure GST1. The second grid structure GST2 may include the shield fence layer 48p.

Due to the grid gap AR and the shield fence layer 48p, the cross-talk issue may be reduced, and the sensitivity of the image sensor may be improved.

FIG. 4C is an enlarged sectional view illustrating the portion ‘X’ of the image sensor of FIG. 4A. For concise description, a previously described element may be identified by the same reference number without repeating an overlapping description thereof.

Referring to FIG. 4C, each of the fence layer 48 of the first grid structure GST1 and the shield fence layer 48p of the second grid structure GST2 may further include an etch stop layer 484. The etch stop layer 484 may be disposed between the upper fence layer 483 and the intervening fence portion 501. An inner side surface of the etch stop layer 484 may be in contact with the protruding fence portion 503.

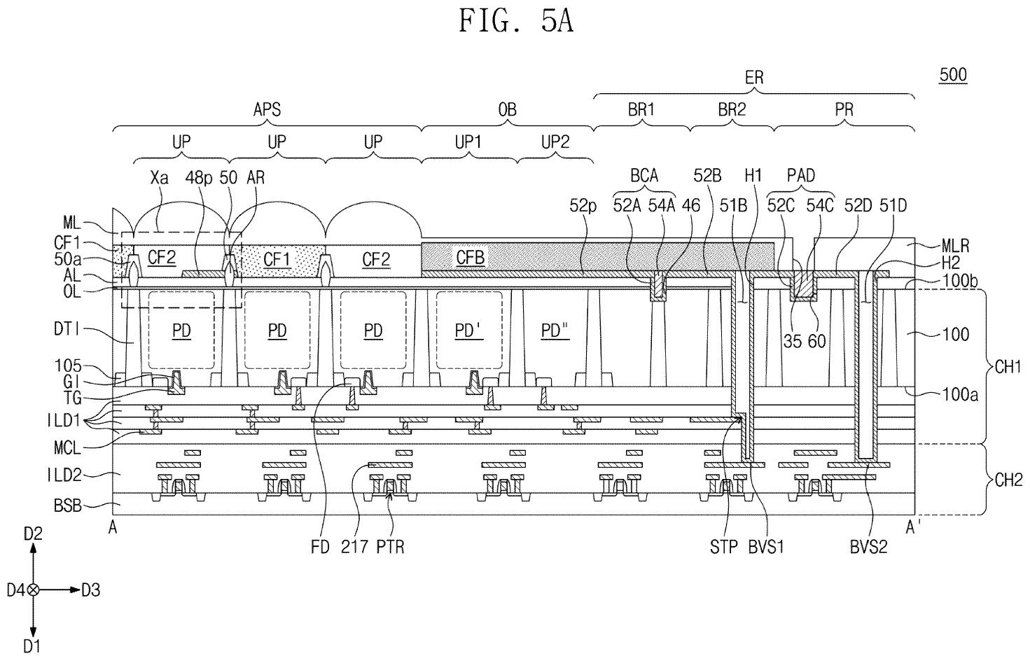

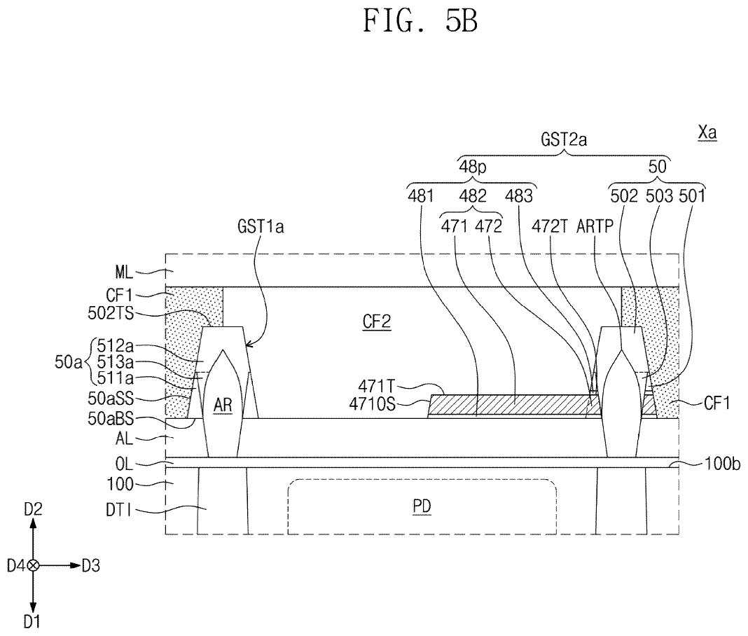

FIG. 5A is a sectional view, which is taken along the line A-A′ of FIG. 3 to illustrate an image sensor according to an example embodiment of the inventive concept. FIG. 5B is an enlarged sectional view illustrating a portion ‘X’ of FIG. 5A. For concise description, a previously described element may be identified by the same reference number without repeating an overlapping description thereof.

Referring to FIGS. 5A and 5B, a first grid structure GST1a may include an insulating fence 50a, and a second grid structure GST2a may include an insulating fence 50a and the shield fence layer 48p. The first grid structure GST1a may include only the insulating fence 50a. In other words, the first grid structure GST1a may not include an element corresponding to the shield fence layer 48p of the second grid structure GST2a. The first grid structure GST1a may include an insulating material.

The insulating fence 50a of the first grid structure GST1a may include an intervening portion 511a in contact with the anti-reflection layer AL, a protruding portion 513a between the intervening portion 511a and the grid gap AR, and a body portion 512a on the protruding portion 513a. A bottom surface of the insulating fence 50a of the first grid structure GST1a may be in contact with the anti-reflection layer AL. A bottom surface of the intervening portion 511a of the insulating fence 50a of the first grid structure GST1a may be in contact with the anti-reflection layer AL. The grid gap AR of the first grid structure GST1a may be defined by an inner side surface of the protruding portion 513a, an exposed inner side surface of the anti-reflection layer AL, and an exposed top surface of the fixed charge layer OL.

A side surface 50aSS of the insulating fence 50a of the first grid structure GSTla may be inclined at an angle. The side surface 50aSS of the insulating fence 50a of the first grid structure GST1a may be in contact with the anti-reflection layer AL. A bottom surface 50aBS of the insulating fence 50a of the first grid structure GST1a may be in contact with the anti-reflection layer AL.

The second grid structure GST2a may include the shield fence layer 48p between the insulating fence 50 and the anti-reflection layer AL. While the bottom surface 50aBS of the insulating fence 50a of the first grid structure GST1 may be in contact with the anti-reflection layer AL, at least a portion of the insulating fence 50 of the second grid structure GST2 may be spaced apart from the anti-reflection layer AL.

The shield fence layer 48p of the second grid structure GST2 may include the lower fence layer 481 on the anti-reflection layer AL, the conductive fence layer 482 on the lower fence layer 481, and the upper fence layer 483 on the conductive fence layer 482.

The conductive fence layer 482 may include the first conductive fence layer 471 and the second conductive fence layer 472. A level of the top surface 471T of the first conductive fence layer 471 may be lower than a level of the top surface 472T of the second conductive fence layer 472.

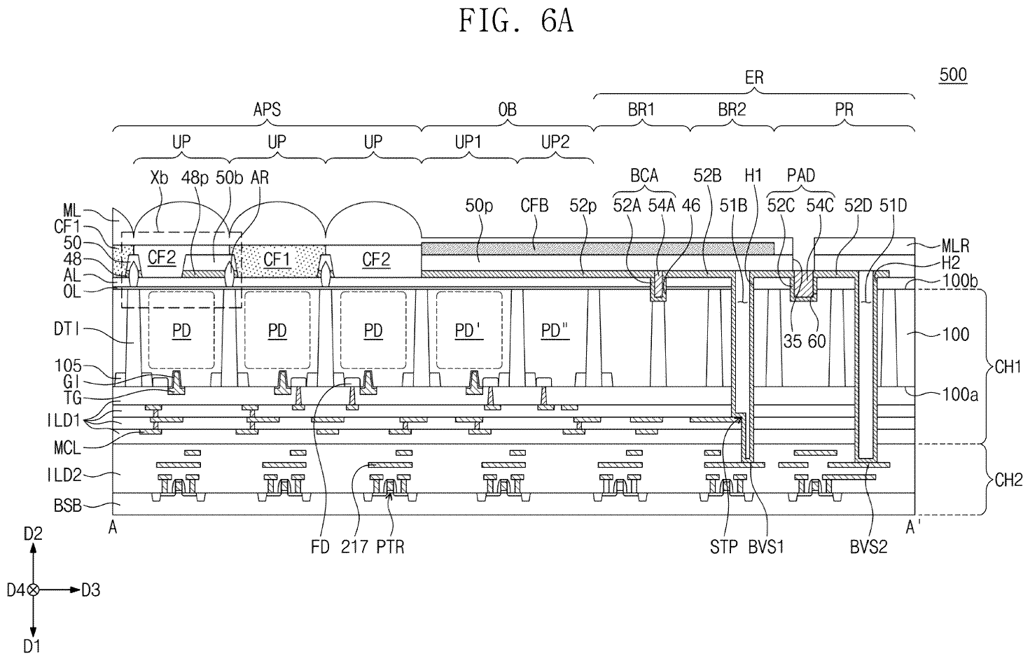

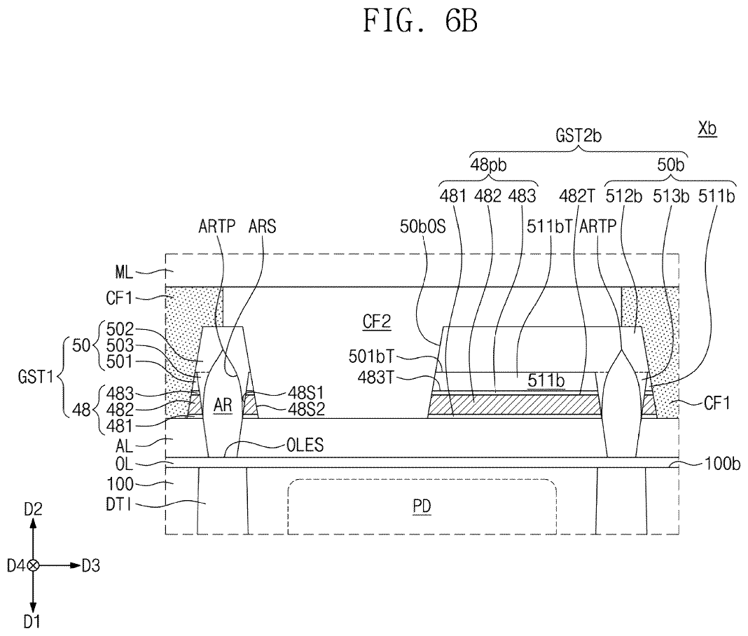

FIG. 6A is a sectional view, which is taken along the line A-A′ of FIG. 3 to illustrate an image sensor according to an example embodiment of the inventive concept. FIG. 6B is an enlarged sectional view illustrating a portion ‘X’ of FIG. 6A. For concise description, a previously described element may be identified by the same reference number without repeating an overlapping description thereof.

Referring to FIGS. 6A and 6B, the first grid structure GST1 may include the fence layer 48 and the insulating fence 50 on the fence layer 48. A second grid structure GST2b may include a shield fence layer 48pb and an insulating fence 50b on the shield fence layer 48pb.

The insulating fence 50b of the second grid structure GST2b may include an intervening portion 511b on the shield fence layer 48pb, a protruding portion 513b between the intervening portion 511b and the grid gap AR, and a body portion 512b on the protruding portion 513b. A top surface of the shield fence layer 48pb of the second grid structure GST2b may be fully covered by the insulating fence 50b. An outer side surface 50bOS of the insulating fence 50b may be inclined at an angle. The intervening portion 511b of the insulating fence 50b may be extended to a region on the shield fence layer 48pb.

The shield fence layer 48p may include the lower fence layer 481 on the anti-reflection layer AL, the conductive fence layer 482 on the lower fence layer 481, and the upper fence layer 483 on the conductive fence layer 482. A top surface 482T of the conductive fence layer 482 may be in contact with the upper fence layer 483. A top surface 483T of the upper fence layer 483 may be in contact with the intervening portion 511b of the insulating fence 50b.

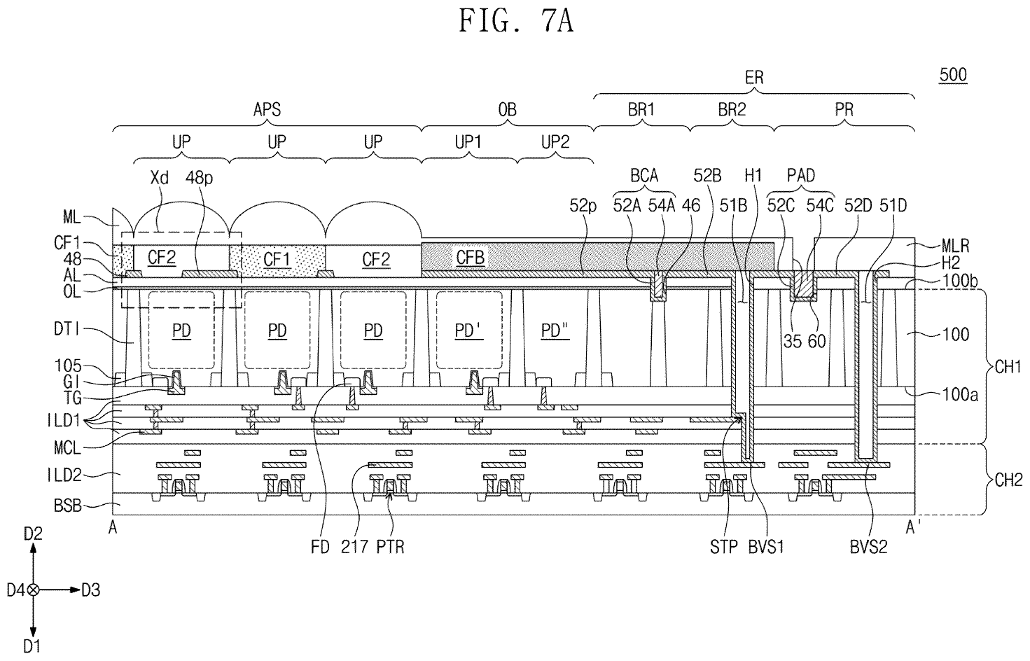

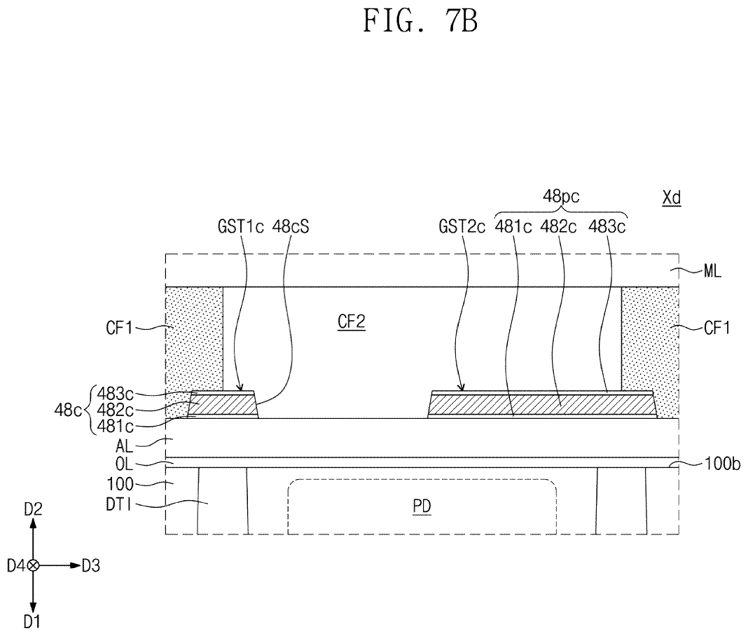

FIG. 7A is a sectional view, which is taken along the line A-A′ of FIG. 3 to illustrate an image sensor according to an example embodiment of the inventive concept. FIG. 7B is an enlarged sectional view illustrating a portion ‘X’ of FIG. 7A. For concise description, a previously described element may be identified by the same reference number without repeating an overlapping description thereof.

Referring to FIGS. 7A and 7B, a first grid structure GST1c may include a fence layer 48c. A topmost surface of the fence layer 48c of the first grid structure GST1c may be in contact with a corresponding one of the color filters CF1 and CF2.

The fence layer 48c of the first grid structure GST1c may include a lower fence layer 481c on the anti-reflection layer AL, a conductive fence layer 482c on the lower fence layer 481c, and an upper fence layer 483c on the conductive fence layer 482c. A side surface 48cS of the fence layer 48c may be inclined at an angle.

A second grid structure GST2c may include a fence layer 48pc. The fence layer 48pc of the second grid structure GST2c may include the lower fence layer 481c on the anti-reflection layer AL, the conductive fence layer 482c on the lower fence layer 481c, and the upper fence layer 483c on the conductive fence layer 482c.

A width of the first grid structure GST1c may be smaller than a width of the second grid structure GST2c. The largest width of the first grid structure GSTlc may be smaller than the largest width of the second grid structure GST2c. The width of the first grid structure GST1c may decrease as a distance from the second surface 100b of the substrate 100 increases.

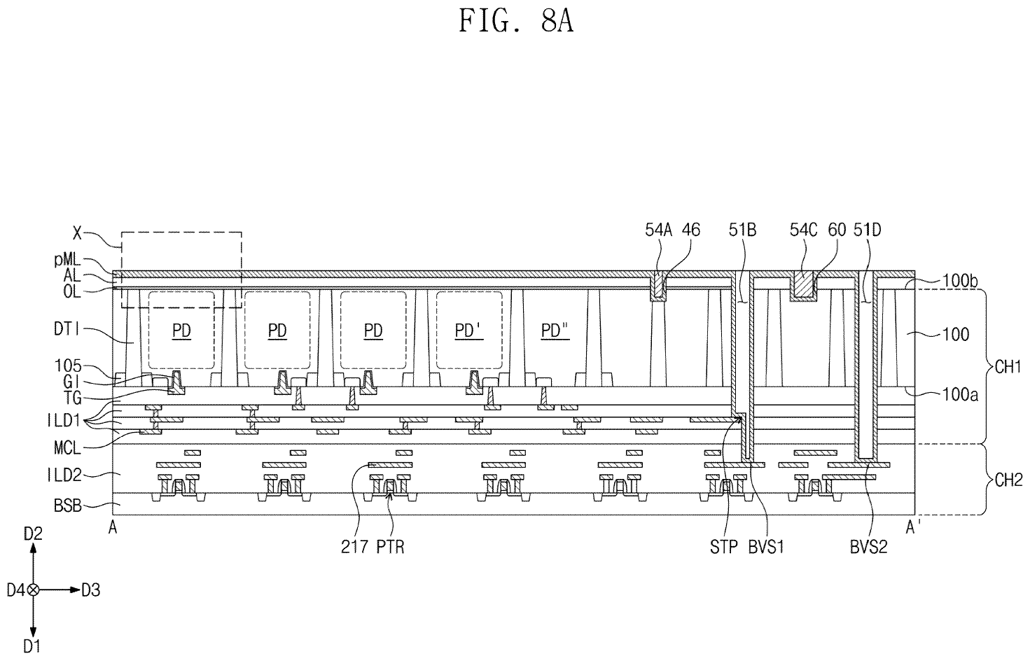

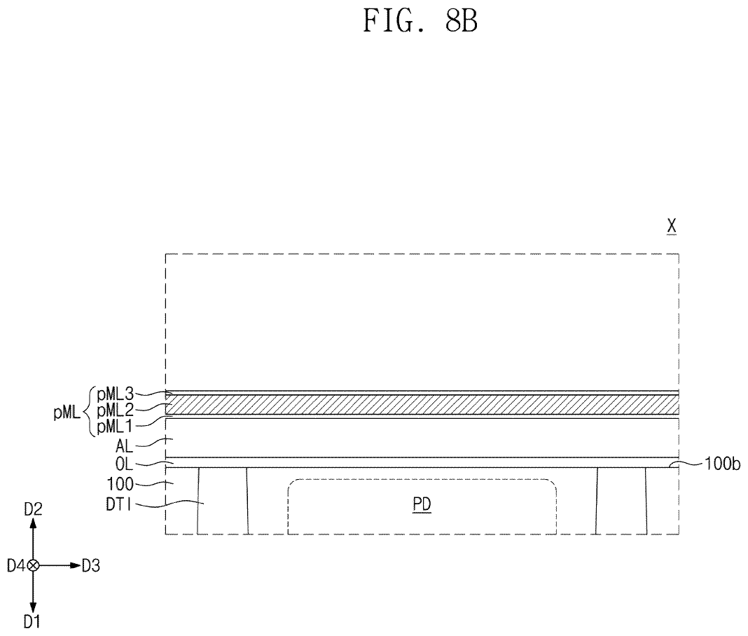

FIGS. 8A, 9A, 10A, 11A, 12A, and 13A are sectional views, which are taken along the line A-A′ of FIG. 3 to illustrate a method of fabricating an image sensor, according to an example embodiment of the inventive concept. FIGS. 8B, 9B, 10B, 11B, 12B, and 13B are enlarged sectional views illustrating the portion ‘X’ of FIG. 4 and illustrating a method of fabricating an image sensor, according to an example embodiment of the inventive concept. For concise description, a previously described element may be identified by the same reference number without repeating an overlapping description thereof.

Referring to FIGS. 8A and 8B, the second sub-chip CH2 having the structure of FIG. 4A and the first sub-chip CH1 bonded to the second sub-chip CH2 may be prepared. The bonding of the first sub-chip CH1 to the second sub-chip CH2 may include connecting the first sub-chip CH1 to the second sub-chip CH2 such that the first interlayer insulating layer ILD1 is in contact with a second interlayer insulating layer IL2.

The fixed charge layer OL may be formed on the first sub-chip CH1. The fixed charge layer OL may be formed of or include an oxide material. The anti-reflection layer AL may be formed on the fixed charge layer OL. After the formation of the anti-reflection layer AL, the back-side contact trench 46 may be formed to penetrate the anti-reflection structure AL and a portion of the substrate 100, and the back-side pad trench 60 may be formed to penetrate the anti-reflection structure AL and a portion of the substrate 100. Trenches may be formed at regions where the first and second back-side via patterns BVS1 and BVS2 will be formed.

Next, a preliminary isolation liner pML may be formed on the anti-reflection structure AL and along inner surfaces of the trenches. The first and second back-side via patterns BVS1 and BVS2 may be formed. The back-side pad trench 60 may be filled with the pad metal pattern 54c, and the back-side contact trench 46 may be filled with the contact metal pattern 54A. The first and second low-refraction protection patterns 51B and 51D may be respectively formed on the first and second back-side via patterns BVS1 and BVS2 to fill the trenches.

FIG. 8B illustrates a detailed structure of the preliminary isolation liner pML. The preliminary isolation liner pML may include a first preliminary isolation liner layer pML1, a second preliminary isolation liner layer pML2 on the first preliminary isolation liner layer pML1, and a third preliminary isolation liner layer pML3 on the second preliminary isolation liner layer pML2. A thickness of the second preliminary isolation liner layer pML2 may be larger than a thicknesses of the first and third preliminary isolation liner layers pML1 and pML3. The second preliminary isolation liner layer pML2 may be formed of or include a metallic material.

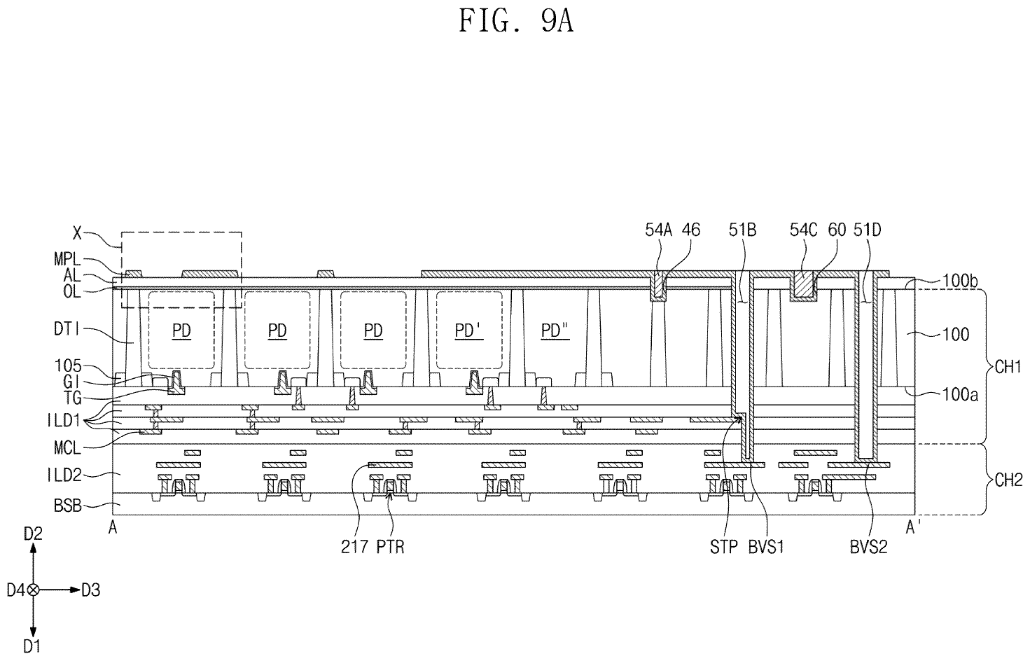

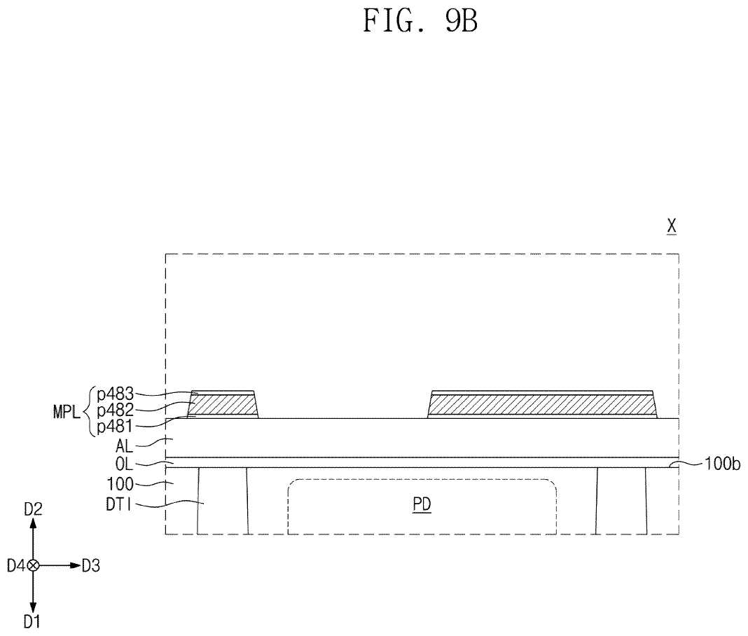

Referring to FIGS. 9A and 9B, the first preliminary liner pML may be patterned to form a preliminary fence layer MPL. The patterning of the first preliminary liner pML may include forming a mask on the first preliminary liner pML, performing a photolithography process and an etching process, and performing a cleaning process.

The patterning of the first preliminary liner pML may be performed such that a portion of the top surface of the anti-reflection layer AL on the photoelectric conversion part PD is exposed by the preliminary fence layer MPL. The patterning of the first preliminary liner pML may be performed such that the top surface of the anti-reflection layer AL on the black photoelectric conversion part PD′ and the dummy region PD″ is fully covered with the preliminary fence layer MPL.

The preliminary fence layer MPL may include a first preliminary fence layer p481, which is formed by patterning the first preliminary isolation liner layer pML1, a second preliminary fence layer p482, which is formed by patterning the second preliminary isolation liner layer pML2, and a third preliminary fence layer p483, which is formed by patterning the third preliminary isolation liner layer pML3. The first to third preliminary fence layer p481 to p483 may be patterned to have different widths from each other.

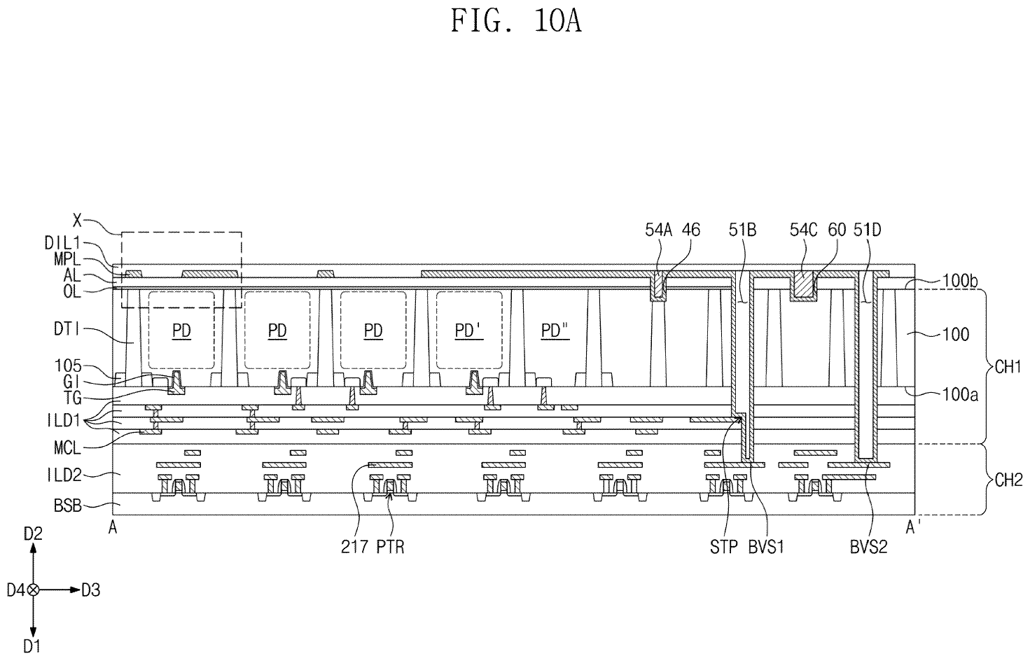

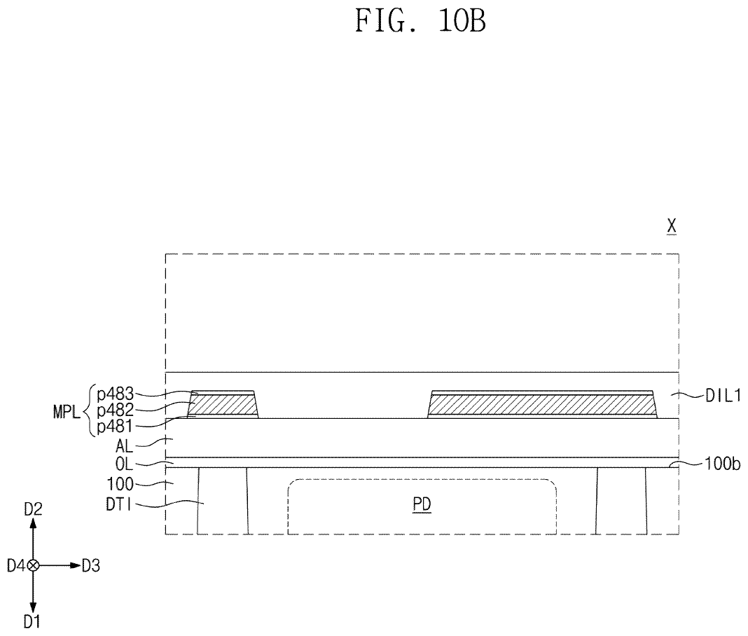

Referring to FIGS. 10A and 10B, a first insulating layer DIL1 may be formed on the preliminary fence layer MPL. The first insulating layer DIL1 may be formed to cover top and side surfaces of the preliminary fence layer MPL. The first insulating layer DIL1 may include an insulating material.

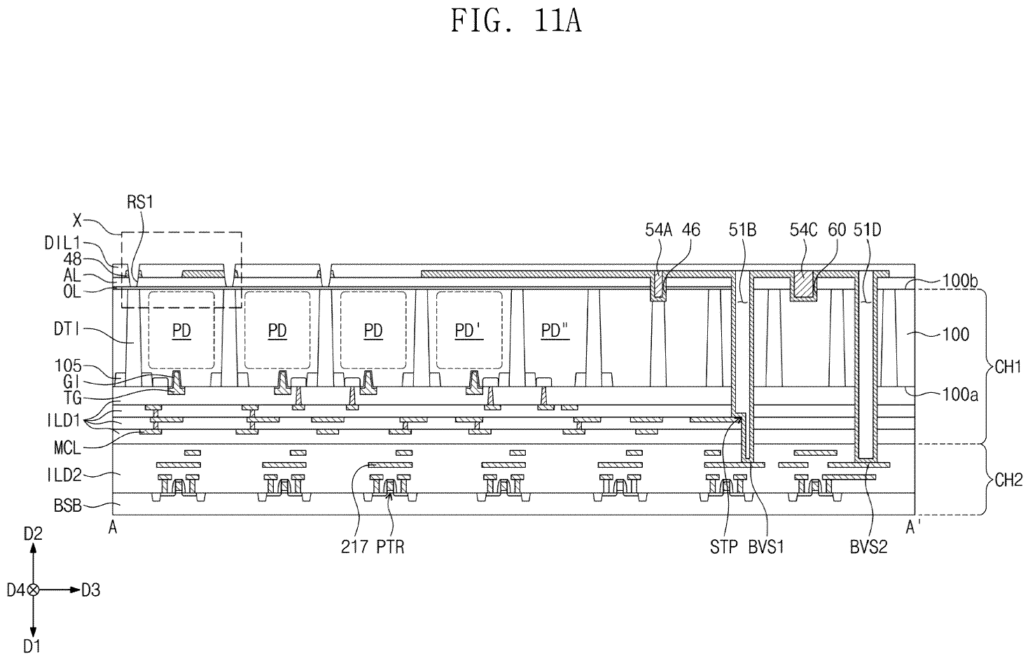

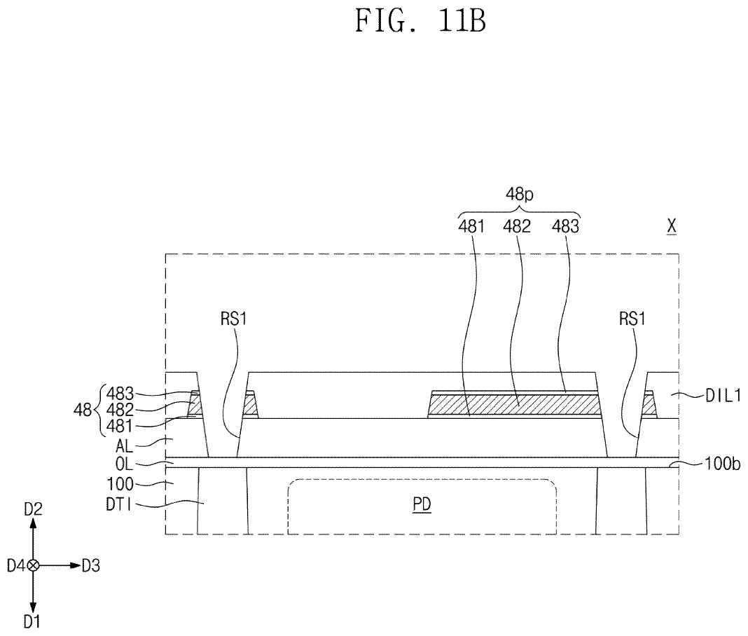

Referring to FIGS. 11A and 11B, a first recess RS1 may be formed to penetrate the first insulating layer DIL1, the preliminary fence layer MPL, and the anti-reflection layer AL. As a result of the formation of the first recess RS1, the fence layer 48 may be formed.

The first preliminary fence layer p481 may form the lower fence layer 481. The second preliminary fence layer p482 may form the conductive fence layer 482. The third preliminary fence layer p483 may form the upper fence layer 483.

The first recess RS1 may be formed to penetrate the preliminary fence layer MPL having a large width and the anti-reflection layer AL. As a result of the formation of the first recess RS1, a preliminary shield fence layer 48p may be formed. A top surface of the fixed charge layer OL may be exposed by the first recess RS1.

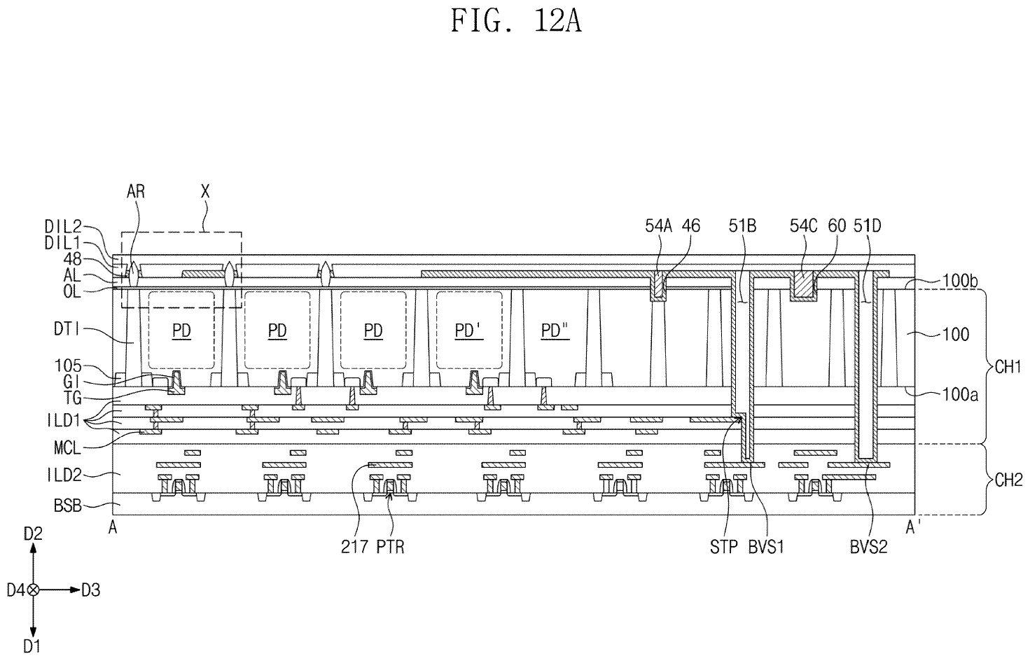

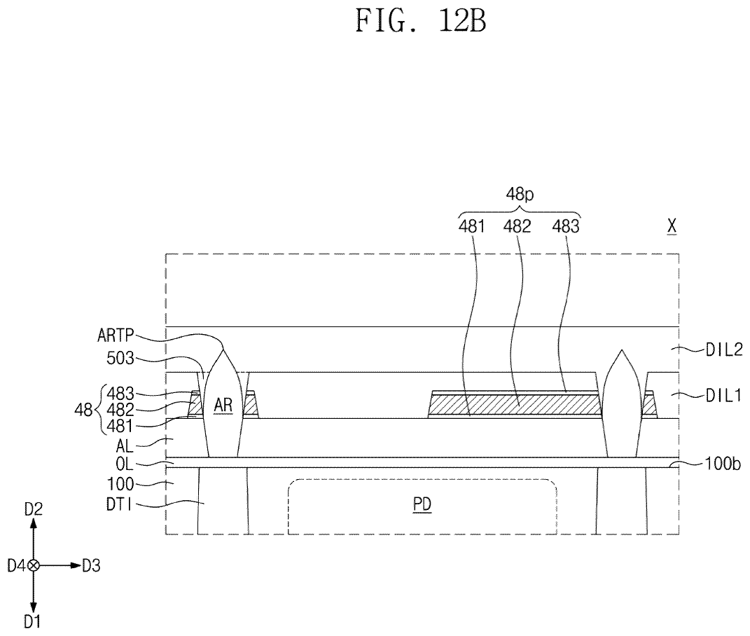

Referring to FIGS. 12A and 12B, a patterning process may be performed to form the grid gap AR on the first recess RS1 and the first insulating layer DIL1, and then, a second insulating layer DIL2 may be formed. The second insulating layer DIL2 may be formed of or include the same material as the first insulating layer DIL1. In an embodiment, the second insulating layer DIL2 may be formed of or include a material different from the first insulating layer DIL1. Thus, the grid gap AR may be formed. The gap topmost point ARTP, which is defined at the topmost level of the grid gap AR, may be placed in the second insulating layer DIL2.

The second insulating layer DIL2 may be interposed between the fence layer 48 and the grid gap AR. The second insulating layer DIL2 may be formed to cover a side surface of the fence layer 48. Thus, the protruding fence portion 503 of FIG. 4B may be formed.

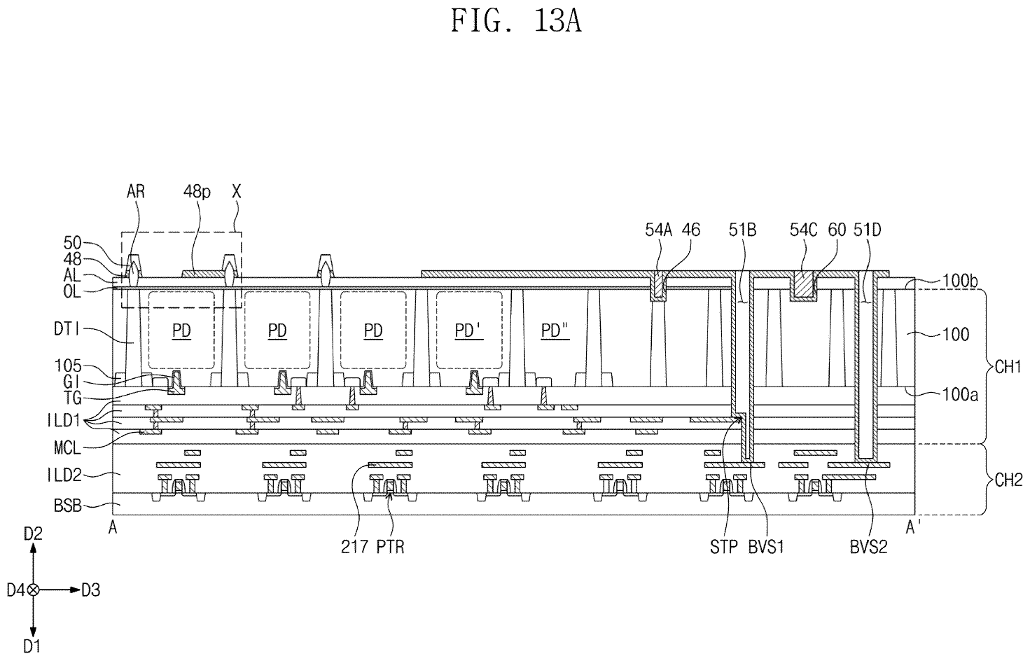

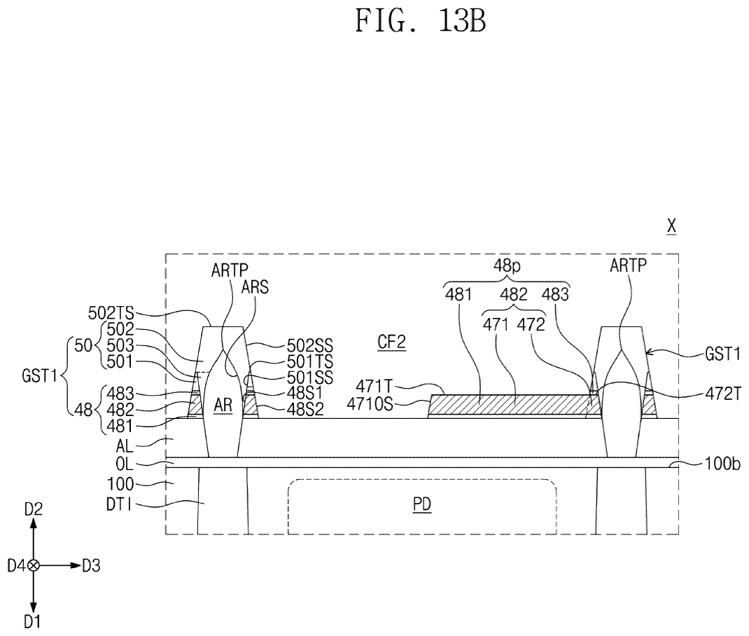

Referring to FIGS. 13A and 13B, a patterning process may be performed to partially remove the first and second insulating layers DIL1 and DIL2. A portion of the first insulating layer DIL1 may be left on the fence layer 48. The portion of the first insulating layer DIL1 left on the fence layer 48 may have a decreasing width as a distance from the second surface 100b of the substrate 100 increases. The portion of the first insulating layer DIL1 left on the fence layer 48 may form the intervening fence portion 501.

A portion of the second insulating layer DIL2 may be removed. A portion of the second insulating layer DIL2, which is located on the first insulating layer DIL1 and the grid gap AR, may be left, and the remaining portion of the second insulating layer DIL2 may be removed. The body fence portion 502, which is located at a level higher than the top surface 501TS of the intervening fence portion 501, and the protruding fence portion 503, which is located at a level lower than the top surface 501TS of the intervening fence portion 501, may be left, and the remaining portion of the second insulating layer DIL2 may be removed. The protruding fence portion 503 may be in contact with the side surface 501SS of the intervening fence portion 501. The side surface 501SS of the intervening fence portion 501 may be covered with the protruding fence portion 503. The inner side surface 48S1 of the fence layer 48 may be in contact with the protruding fence portion 503. Accordingly, the insulating fence 50 may be formed on the fence layer 48.

The partial removal of the first and second insulating layers DIL1 and DIL2 may include removing the first and second insulating layers DIL1 and DIL2 to expose the outer side surface 48S2 of the fence layer 48 and the outer side surface 471OS of the shield fence layer 48p. The partially removal of the first and second insulating layers DIL1 and DIL2 may include removing the first and second insulating layers DIL1 and DIL2 to expose the top surface 502TS of the body fence portion 502 and the side surface 502SS of the body fence portion 502.

In the case where the shield fence layer 48p is patterned, the conductive fence portion 482 may be patterned to have a stepwise structure. In this case, the shield fence layer 48p may be formed to include the first conductive fence layer 471, which has the top surface 471T exposed to the outside, and the second conductive fence layer 472, which has the top surface 472T in contact with the upper fence layer 483. A level of the top surface 471T of the first conductive fence layer 471 may be lower than a level of the top surface 472T of the second conductive fence layer 472.

As a result, the first and second grid structures GST1 and GST2 may be formed.

Next, referring back to FIGS. 4A and 4B, the color filters CF1 and CF2 may be formed between the first and second grid structures GST1 and GST2. The optical black pattern CFB may be formed. The micro lenses ML may be formed on the color filters CF1 and CF2. The lens residual layer MLR may be formed on the optical black pattern CFB. In the pad region PR, the opening 35 may be formed in the lens residual layer MLR to expose the back-side conductive pad PAD. The image sensor may be formed to have the structure of FIGS. 3, 4A, and 4B, for example.

In an image sensor according to an embodiment of the inventive concept, a grid structure may be disposed between color filters. In this case, a grid gap may be formed in the grid structure. Due to the grid gap, it may be possible to reduce a cross-talk issue in the image sensor.

In an image sensor according to an embodiment of the inventive concept, a grid structure may be disposed between color filters. In this case, a portion of the grid structure may include a shield fence layer. Accordingly, it may be possible to improve the reliability and optical performance of the image sensor.

While example embodiments of the inventive concept have been particularly shown and described, it will be understood by one of ordinary skill in the art that variations in form and detail may be made therein without departing from the spirit and scope of the attached claims and their equivalents.

What is claimed is:

1. An image sensor, comprising:
a semiconductor substrate that has a first surface and a second surface that are opposite to each other;
an anti-reflection layer on the semiconductor substrate;
color filters on the anti-reflection layer;
grid structures disposed between adjacent color filters among the color filters; and
a grid gap defined in each of the grid structures,
wherein the grid structures comprise:
a first grid structure comprising an insulating fence; and
a second grid structure comprising an insulating fence, the second grid structure having a width larger than the first grid structure,
wherein the first grid structure is spaced apart from the second grid structure, and
wherein the grid gap is defined as a space that is extended from the insulating fence to the anti-reflection layer.

2. The image sensor of claim 1, wherein inner surfaces of the grid structures defining the grid gap are defined as a gap side surface,
the gap side surface comprises a curved portion.

3. The image sensor of claim 1, wherein the first grid structure further comprises a fence layer, which is provided on or below the insulating fence and includes a conductive material, and
wherein the second grid structure further comprises a shield fence layer provided below the insulating fence and being wider than the fence layer.

4. The image sensor of claim 1, wherein the first grid structure further comprises a fence layer, which is provided on or below the insulating fence,
wherein the insulating fence included in the first grid structure or the second grid structure comprises:
a protruding fence portion in contact with a side surface of the fence layer;
a body fence portion on the protruding fence portion; and
an intervening fence portion between a color filter and the protruding fence portion,
wherein an outer side surface of the protruding fence portion is in contact with an inner side surface of the fence layer, and
wherein an inner side surface of the protruding fence portion defines the grid gap.

5. The image sensor of claim 4, wherein an outer side surface of the body fence portion is spaced apart from the outer side surface of the protruding fence portion.

6. The image sensor of claim 4, wherein the fence layer comprises:
a lower fence layer on the anti-reflection layer;
a conductive fence layer on the lower fence layer; and
an upper fence layer on the conductive fence layer, and
wherein the protruding fence portion is provided between the upper fence layer and the conductive fence layer and the grid gap.

7. The image sensor of claim 4, wherein a gap topmost point, which is defined at a topmost level of the grid gap, is provided between a topmost surface of the body fence portion and a topmost surface of the intervening fence portion.

8. The image sensor of claim 1, further comprising a fixed charge layer between the semiconductor substrate and the anti-reflection layer,
wherein a top surface of the fixed charge layer is exposed by the grid gap.

9. The image sensor of claim 1, wherein the second grid structure comprises a shield fence layer between the insulating fence and the anti-reflection layer,
wherein a bottom surface of the insulating fence of the first grid structure is in contact with the anti-reflection layer, and
wherein at least a portion of the insulating fence of the second grid structure is spaced apart from the anti-reflection layer.

10. An image sensor, comprising:
a semiconductor substrate having a first surface and a second surface, the second surface being opposite to the first surface;
a fixed charge layer on the semiconductor substrate;
an anti-reflection layer on the fixed charge layer;
color filters on the anti-reflection layer;
grid structures disposed between adjacent color filters among the color filters; and
a grid gap defined in each of the grid structures,
wherein the grid structures comprise:
a first grid structure comprising a fence layer and an insulating fence on the fence layer, the fence layer comprising a conductive material; and
a second grid structure comprising a shield fence layer of which a largest width is larger than a width of the fence layer,
wherein the first grid structure is spaced apart from the second grid structure,
wherein a topmost portion of the grid gap in the first grid structure is defined in the insulating fence, and
wherein a top surface of the fixed charge layer is exposed by the grid gap.

11. The image sensor of claim 10, wherein the grid gap is defined by an inner surface of the insulating fence, an exposed inner surface of the anti-reflection layer, and the exposed top surface of the fixed charge layer.

12. The image sensor of claim 10, wherein a gap topmost point, which is defined at a topmost level of the grid gap, is provided between a topmost surface of the fence layer and a topmost surface of the insulating fence.

13. The image sensor of claim 10, wherein the second grid structure further comprises an insulating fence on the shield fence layer,
wherein the insulating fence of the second grid structure comprises:
a protruding fence portion in contact with a side surface of the shield fence layer;
a body fence portion on the protruding fence portion; and
an intervening fence portion between the shield fence layer and the body fence portion, and
wherein the protruding fence portion is disposed between the grid gap and the intervening fence portion.

14. The image sensor of claim 10, further comprising an etch stop layer interposed between the insulating fence and the fence layer.

15. The image sensor of claim 10, wherein the shield fence layer comprises:
a lower fence layer on the anti-reflection layer;
a conductive fence layer on the lower fence layer; and
an upper fence layer on the conductive fence layer, and
wherein a top surface of the upper fence layer is in contact with the insulating fence.

16. The image sensor of claim 10, wherein the shield fence layer comprises:
a lower fence layer on the anti-reflection layer;
a conductive fence layer on the lower fence layer; and
an upper fence layer on the conductive fence layer.

17. The image sensor of claim 10, wherein a width of a bottom surface of the grid gap is smaller than a largest width of the grid gap.

18. An image sensor, comprising:
a substrate having a first surface and a second surface, the second surface being opposite to the first surface;
a transfer gate disposed on the first surface;
a fixed charge layer disposed on the second surface;
an anti-reflection layer on the fixed charge layer;
color filters on the anti-reflection layer;
grid structures disposed between adjacent color filters among the color filters; and
a grid gap defined in each of the grid structures,
wherein the grid structures comprise:
a first grid structure comprising a fence layer and an insulating fence on the fence layer, the fence layer comprising a conductive material; and
a second grid structure spaced apart from the first grid structure, the second grid structure comprising a shield fence layer wider than the fence layer and an insulating fence on the shield fence layer,
wherein the grid gap is defined by the insulating fence and the anti-reflection layer,
wherein the insulating fence included in the first grid structure comprises:
a protruding fence portion of which an outer side surface is in contact with a side surface of the first grid structure,
a body fence portion on the protruding fence portion; and
an intervening fence portion between a color filter and the protruding fence portion, and
wherein the grid gap in the first grid structure is defined by the protruding fence portion and a side surface of the body fence portion.

19. The image sensor of claim 18, further comprising an etch stop layer interposed between the insulating fence and the fence layer.

20. The image sensor of claim 18, wherein the fixed charge layer comprises aluminum oxide, and
wherein a portion of a top surface of the fixed charge layer is exposed by the grid gap.
